(19) United States
(12) Patent Application Publication
(10) Pub. No.: US 2014/0362533 A1
(43) Pub. Date: Dec. 11, 2014

(54) ELECTRONIC CONTROL APPARATUS FOR VEHICLE

(71) Applicant: Hyundai Autron Co., Ltd., Seongnam-si (KR)

(72) Inventors: Chang Geun Shin, Yongin-si (KR); Sun Jae Yang, Gunpo-si (KR); Dong Gi Lee, Incheon (KR); Yeon Chul Choo, Seoul (KR); Chang Ju Kim, Uijeongbu-si (KR)

(73) Assignee: Hyundai Autron Co., Ltd., Seongnam-si (KR)

(21) Appl. No.: 14/139,838

(22) Filed: Dec. 23, 2013

(30) Foreign Application Priority Data
Jun. 7, 2013 (KR) 10-2013-0065298

(51) Int. Cl. H05K 7/14; H05K 7/20

(52) U.S. Cl. CPC H05K 7/1427; H05K 7/2039
USPC 361/707

(57) ABSTRACT

The present disclosure relates to an electronic control apparatus into which an printed circuit board is inserted in a sliding manner, and the electronic control apparatus of the present disclosure includes: an printed circuit board (PCB) and has one surface on which a heating element is mounted, and a corresponding surface on which a heat radiating material is applied; a connector cover which includes a connector electrically connected and coupled to the electronic circuit board, and a cover coupling portion for coupling a housing; and a housing body to which the PCB is tightly attached and assembled in a sliding manner, in which one or more projections are formed on both side surfaces in the housing body, one or more grooves are formed in both side surfaces of the electronic circuit board, the PCB is inserted and guided into the housing body in a sliding manner.

### CROSS-REFERENCE TO RELATED APPLICATIONS

This application is based on and claims priority from Korean Patent Application No. 10-2013-0065298, filed on Jun. 7, 2013, the disclosure of which is incorporated herein in its entirety by reference.

### TECHNICAL FIELD

The present disclosure relates to an electronic control apparatus for a vehicle, and more particularly, to an electronic control apparatus which is an electronic control apparatus such as an engine electronic control unit (ECU) for a vehicle and has a structure in which an electronic control board, which is coupled to a housing in a sliding manner, may be tightly fixed to the housing.

### BACKGROUND

In general, an electronic control apparatus such as an ECU, which electronically controls various types of devices, is equipped in a vehicle. The electronic control apparatus receives information from sensors or switches that are installed at each part of the vehicle. The electronic control apparatus serves to perform various electronic controls for promoting improvement of a riding quality and safety of the vehicle or providing various items of convenience to a driver and a passenger by processing the received information.

For example, the electronic control apparatus such as the ECU, which controls states of an engine, an automatic transmission, an anti-lock brake system (ABS), and the like in the vehicle using a computer, also serves to control all parts in the vehicle, such as a driving system, a braking system, and a steering system as well as the automatic transmission as the vehicle and the computer have been developed in terms of performance.

The electronic control apparatus such as the ECU has a structure that includes a case which includes an upper cover and a lower base, a printed circuit board (PCB) which is accommodated in the case, a connector which is coupled to a front end of the PCB so as to be connected to an external socket, and the like.

The case has a structure in which the cover and the base are assembled together with the PCB while covering the PCB, and particularly, the connector, which is interposed between the cover and the base when the cover and the base are assembled, forms a sealing structure with the cover side and the base side.

The electronic control apparatus includes a high integrated control circuit means and thus requires a predetermined sealing structure that may prevent external moisture or foreign substances from flowing into the electronic control apparatus, and the electronic control apparatus mainly adopts a sealing structure in which the cover and the base are typically assembled together with the connector in a state in which sealing materials are inserted on binding parts between the cover and the base and the connector.

Meanwhile, the electronic control apparatus may be assembled in a sliding manner. Here, the electronic control apparatus is assembled by pushing the PCB into a one-piece housing in a sliding manner, and in this case, the PCB is tightly attached to the housing in a sliding manner, and thus, applied thermal glue is pushed out during an assembly process such that the thermal glue may not be completely adhered to the entire housing. Therefore, performance of radiating heat through the housing may deteriorate at a portion of the PCB where the thermal glue is not applied.

According to the slide type electronic control apparatus in the related art, additional devices such as clips or screws are required as a means for tightly fixing the PCB to the housing in order to prevent the PCB and components from being damaged by vibration or the like.

### SUMMARY

The present disclosure has been made in an effort to provide an electronic control apparatus which has a PCB guide and a fixing hole formed in a housing so as to maintain a state in which thermal glue applied on a PCB is not damaged and applied as it is during an assembly process when the electronic control apparatus is assembled in a sliding manner, thereby preventing damage to a heat radiating material and improving heat radiating performance.

The present disclosure has been made in an effort to provide an electronic control apparatus having PCB fixing means that may tightly fix a PCB to a housing without using separate means such as screws or clips for tightly fixing the PCB to the housing.

An exemplary embodiment of the present disclosure provides an electronic control apparatus including: an electronic circuit board (PCB) which electrically controls each part of a vehicle, and has one surface on which a heating element is mounted, and a corresponding surface on which a heat radiating material is applied; a connector cover which includes a connector electrically connected and coupled to the electronic circuit board, and a cover coupling portion for coupling a housing; and a housing body to which the electronic circuit board is tightly attached and assembled in a sliding manner, in which one or more projections, which guide the electronic circuit board to be inserted in a sliding manner, are formed on both side surfaces in the housing body, one or more grooves, which have shapes corresponding to the shapes of the projections, are formed in both side surfaces of the electronic circuit board, the electronic circuit board is inserted and guided into the housing body in a sliding manner along upper surfaces of the projections of the housing body, and the electronic circuit board is inserted to lower surfaces of the projections at a position where the projections of the housing body and the grooves of the electronic circuit board face each other such that the electronic circuit board is tightly fixed on a bottom surface of the housing body.

The electronic circuit board may be fixed on the bottom surface of the housing body so as to have pressing force through the projections of the housing body.

The heat radiating material may be liquid type glue having conductivity and adhesive property.

The projections of the housing body may be formed to be positioned at a position having a height which is about 90% of a height of a side surface of the housing body.

An interval between the lower surface of the projection and the bottom surface of the housing body may be smaller than a thickness of the electronic circuit board.

According to the exemplary embodiment of the present disclosure, the PCB guide and the fixing hole are provided in the housing, thereby preventing damage to the heat radiating material applied on the PCB and improving heat radiating performance when the electronic control apparatus is assembled in a sliding manner.

The PCB may be tightly attached to the housing by pressing force caused by the fixing hole provided in the housing, thereby maximizing heat radiating performance.

The PCB may be tightly fixed to the housing without using separate means such as screws or clips for tightly fixing the PCB to the housing, thereby reducing manufacturing costs.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view schematically illustrating the interior of a slide type electronic control apparatus.

FIG. 2 is a view illustrating an electronic control apparatus according to an exemplary embodiment of the present disclosure.

FIG. 3 is a view illustrating a bottom side of a PCB of the electronic control apparatus according to the exemplary embodiment of the present disclosure.

FIG. 4 is a view schematically illustrating a process of coupling a housing and the PCB of the electronic control apparatus according to the exemplary embodiment of the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

Hereinafter, exemplary embodiments according to the present disclosure will be described in detail with reference to the accompanying drawings. A configuration of the present disclosure and an operation and an effect according to the configuration of the present disclosure will be clearly understood by the detailed description below. In the following description, the same elements will be designated by the same reference numerals although the elements are illustrated in different drawings, and a detailed explanation of publicly known related configurations may be omitted so as to avoid unnecessarily obscuring the subject matter of the present disclosure.

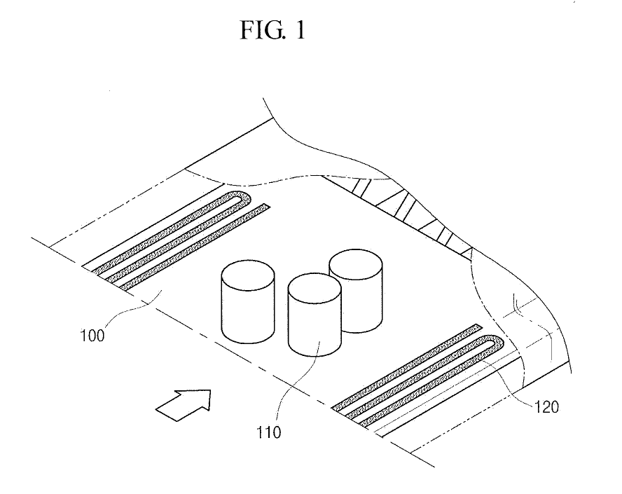

FIG. 1 is a view schematically illustrating the interior of a slide type electronic control apparatus.

The electronic control apparatus refers to a component having an electronic control element, for example, integrated control circuit means, such as a PCB 100, which electrically controls each part of a vehicle, and requires a heat radiating structure for radiating heat, which is generated from heating elements 110 positioned on the PCB 100, to the atmosphere, and a housing structure for preventing external moisture or foreign substances from flowing into the electronic control apparatus. The electronic control apparatus has a can type one-piece housing that accommodates the PCB 100 therein.

The electronic control apparatus includes a housing body, a connector cover, and an end housing. The PCB 100 is inserted into a housing body in a sliding manner, and the connector cover includes a cover coupling portion, and a connector.

In this case, the PCB 100 on which thermal glue 120 is applied is inserted into the housing body in a sliding manner such that the PCB 100 is tightly attached and assembled to a lower portion of the housing. Here, the thermal glue 120 may be a thermal conductive material. In a case in which the thermal glue 120 is in a gel state, the thermal glue 120 is cured to fix the thermal glue 120 after the electronic control apparatus is assembled.

Referring to the connector cover, the cover coupling portion and the connector may be separated, or may be integrally formed for waterproof purpose. The cover coupling portion is coupled to the housing body. The connector is coupled and electrically connected to the PCB 100. The connector has a connector pin, and is electrically connected to the PCB 100 through the connector pin. The connector pin may include a plurality of inner pins for connection to the PCB 100, and a plurality of outer pins for connection to the exterior. The connector may be physically coupled to the PCB 100 while being fitted with the PCB 100, and may be electrically connected to the PCB 100 through the inner pins. The connector may have a front end portion that is exposed to the outside, and a rear end portion, and the front end portion and the rear end portion may be integrally formed.

The PCB 100 may have electric elements, heating elements 110, a heat radiating plate, or the like at a top side or a bottom side. The exterior of the connector cover is connected to the connector, and the connector cover is connected to the PCB 100 inside the housing. The PCB 100 has the heating elements 110 on one surface of the PCB 100, and the thermal glue 120 is applied on a side portion of the one surface. The thermal glue 120 is provided to radiate heat generated from the heating elements 110, and a heat radiating pad, a heat radiating plate, liquid type glue, or the like may be used in some cases.

However, in the aforementioned structure, in a case in which the PCB is inserted into the housing in a sliding manner, the gel type thermal glue applied on a lower portion of the PCB is pushed out when the PCB is inserted into the housing, and thereby, the thermal glue may not be completely adhered to the entire housing. Therefore, thermal conductivity through the heat radiating material deteriorates at a portion of the PCB where the thermal glue is not applied, and thereby, performance of radiating heat of the heating elements 110 to the outside through the housing may overall deteriorate.

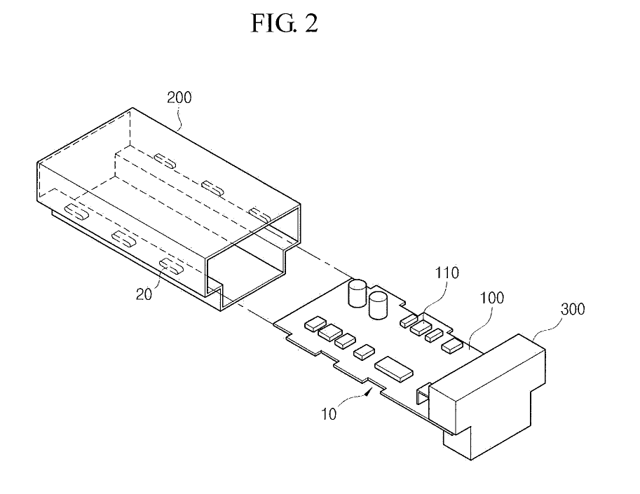

FIG. 2 is a view illustrating the electronic control apparatus according to the exemplary embodiment of the present disclosure.

As illustrated, the housing body 200 of the electronic control apparatus is configured as a one-piece type in which one side is opened so as to assemble the PCB 100 in the housing body 200 in a sliding manner. In this case, projections 20, which protrude inward, are formed on both side surfaces of the housing body. The number of projections 20 is one or more, and may be about three on a side surfaces as illustrated in the drawing.

The projections 20 formed on both side surfaces of the housing serve to guide the electronic circuit board (PCB) 100 so that the electronic circuit board (PCB) 100 may be inserted into the housing body along upper surfaces of the projections 20. Therefore, a shape of the projection 20 may be modified into various shapes as long as the projection 20 may guide the PCB 100 to be seated in the housing body.

The heating elements 110 are mounted at the top side of the PCB 100, and the heat radiating material 120 such as a heat radiating pad, a heat radiating plate, or liquid type glue is provided at the bottom side of the PCB 100. The connector 300 is coupled and electrically connected to the PCB 100.

A plurality of grooves 10 is formed in both side surfaces of the PCB 100 so as to correspond to the projections 20 of the housing 200. Therefore, the PCB 100 is slidingly inserted into the housing 200 along the projections 20, and then the projections 20 of the housing 200 are inserted into the grooves 10 of the PCB 100 at a predetermined position, such that the PCB 100 is tightly attached to a bottom surface of the housing 200.

Thereafter, the PCB 100 is inserted up to an end surface of the housing 200, and as a result, an assembly process is finally completed.

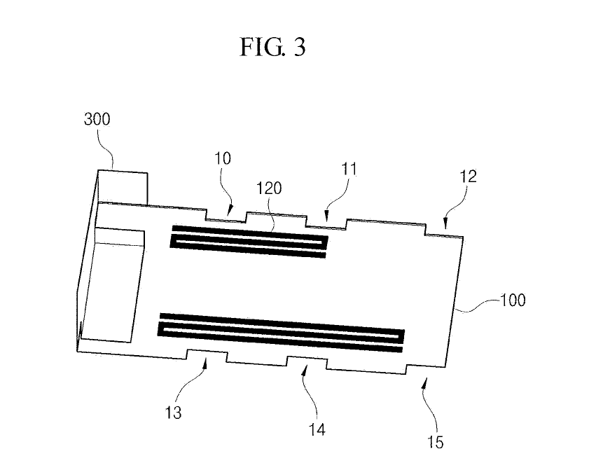

FIG. 3 is a bottom view illustrating the bottom side of the PCB 100 according to the exemplary embodiment of the present disclosure.

The gel type thermal glue 120 is applied on the bottom side of the PCB 100 along corresponding surfaces on which the heating elements 110 are arranged, and the grooves 10, 11, 12, 13, 14, and 15 are formed in both side surfaces of the PCB 100 so as to correspond to the projections 20 of the housing 200.

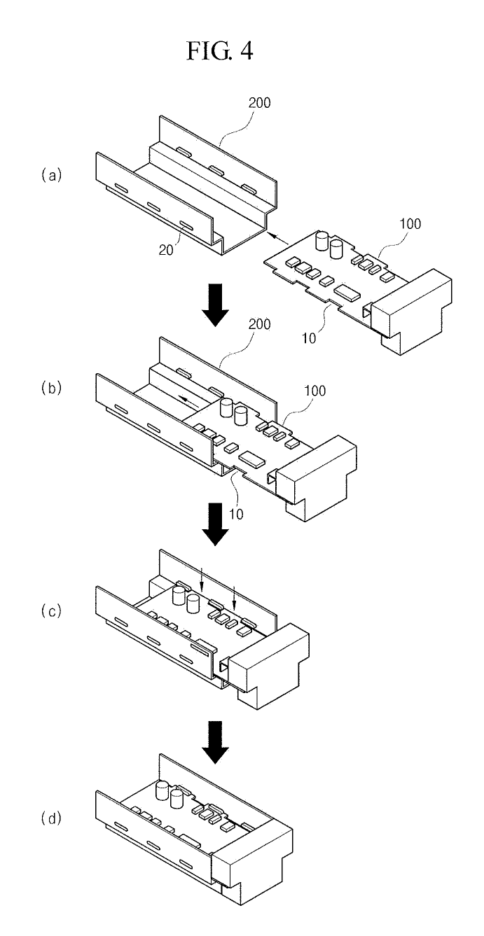

FIG. 4 is a view schematically illustrating a process of coupling the housing 200 and the PCB 100 of the electronic control apparatus according to the exemplary embodiment of the present disclosure.

The top side of the housing 200 is omitted from FIG. 4 for convenience of description in order to illustrate a coupling structure in the housing. The plurality of projections 20 is formed on both side surfaces in the housing 200, and the grooves 10, which correspond to the projections 20, are formed in both side surfaces of the PCB 100. In FIG. 4A, a total of six projections 20 and a total of six grooves 10 are formed, with three on each side.

The projections 20 of the housing body may be positioned at a position having a height which is about 90% of a height of a side surface of the housing body so as to be closer to the bottom surface of the housing, and an interval between the bottom surface of the housing and the projection 20 may be smaller than a width of the PCB 100.

As illustrated in FIG. 4B, the PCB 100 is slidingly inserted into the housing 200 along the upper surfaces of the projections 20 in the housing 200, and the projections 20 serve to guide the insertion of the PCB 100. When the PCB 100 is inserted into the housing 200 approximately 80 to 90%, the PCB 100 is inserted up to a position where the shape of the projection 20 of the housing 200 is fitted with the shape of the groove 10 of the PCB 100, and thereafter, the groove 10 of the PCB 100 is inserted to a lower surface of the projection 20, as illustrated in FIG. 4C. Therefore, the PCB 100 comes into contact with the bottom surface of the housing 200 while being tightly attached to lower surfaces of the projections 20 from the upper surfaces of the projections 20.

Thereafter, as illustrated in FIG. 4D, the PCB 100 is tightly fixed while being finally and slidingly inserted along the lower surfaces of the projections 20 of the housing 200. In this case, the interval between the lower surfaces of the projections 20 of the housing 200 and the bottom surface of the housing body is smaller than a thickness of the PCB 100, and therefore, the PCB 100 may be tightly fixed on the bottom surface of the housing 200 by predetermined pressing force. The pressing force may be received by the projections 20 of the housing.

As such, the PCB 100 is inserted into and fixed to the housing 200 by the projections 20 of the housing 200 and the grooves 10 of the PCB 100, thereby minimizing damage to the thermal glue on the bottom side of the PCB 100 in an assembly process. When the PCB 100 is tightly fixed on the bottom surface of the housing 200 as illustrated in FIG. 4D, the PCB 100 may be tightly fixed by pressing force caused by the projections 20, and therefore, it is not necessary to use separate components such as clips or screws to tightly fix the PCB to the housing unlike the related art.

The PCB 100 is fixed while receiving pressing force through the projections 20 of the housing 200, and as a result, heat generated from the heating elements 110 may be more effectively conducted through the thermal glue 120, thereby overall improving performance of radiating heat generated from the heating elements to the outside through the thermal glue 120 and the housing 200.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An electronic control apparatus for a vehicle comprising:
an printed circuit board (PCB) which electrically controls each part of a vehicle, and has one surface on which a heating element is mounted, and a corresponding surface on which a heat radiating material is applied;
a connector cover which includes a connector electrically connected and coupled to the printed circuit board, and a cover coupling portion for coupling a housing; and
a housing body to which the printed circuit board is tightly attached and assembled in a sliding manner,
wherein one or more projections are formed on both side surfaces in the housing body, the one or more projections guide the printed circuit board to be inserted in a sliding manner one or more grooves grooves are formed in both side surfaces of the printed circuit board, the shapes of the grooves are correspond to the shapes of the projections, the printed circuit board is inserted and guided into the housing body in a sliding manner along upper surfaces of the projections of the housing body, and the printed circuit board is inserted to lower surfaces of the projections at a position where the projections of the housing body and the grooves of the printed circuit board face each other such that the printed circuit board is tightly fixed on a bottom surface of the housing body.

2. The electronic control apparatus of claim 1, wherein the printed circuit board is fixed on the bottom surface of the housing body so as to have pressing force through the projections of the housing body.

3. The electronic control apparatus of claim 1, wherein the heat radiating material is liquid type glue having conductivity and adhesive property.

4. The electronic control apparatus of claim 1, wherein an interval between the lower surface of the projection and the bottom surface of the housing body is smaller than a thickness of the printed circuit board.
